(19) United States
(12) Patent Application Publication
(10) Pub. No.: US 2010/0229916 A1
(43) Pub. Date: Sep. 16, 2010

(54) PROTECTION SYSTEM

(76) Inventor: GERALDINE BECHAMP, Scottsdale, AZ (US)

Correspondence Address: WEISS & MOY PC, 4204 NORTH BROWN AVENUE, SCOTTSDALE, AZ, 85251, US

(21) Appl. No.: 12/720,425

(22) Filed: Mar. 9, 2010

Related U.S. Application Data
(60) Provisional application No. 61/159,445, filed on Mar. 12, 2009.

(51) Int. Cl. H01L 31/042; E04H 15/34; G05B 19/02

(52) U.S. Cl. 136/244; 135/121; 340/825.22

(57) ABSTRACT

An assembly, solar panel, and solar panel protection system have a deployable and retractable flexible resilient mesh barrier which can be extended to cover and protect a surface which is vulnerable to hail and other airborne projectiles. The mesh barrier can be attached to a frame so as to occupy a plane over the surface. The mesh can be held on a powered or unpowered reel and extended on demand. The reel can have an automatically acting controller which extends the mesh responsive to a remote signal such as a warning signal from a weather announcing authority. The mesh barrier can incorporate a heating element to remove accumulated ice.

### REFERENCE TO RELATED APPLICATIONS

This application claims priority to U.S. Provisional Application Ser. No. 61/159,445 titled IMPACT PROTECTOR which was filed on Mar. 12, 2009 by Geri Bechamp of Scottsdale, Ariz., and is hereby incorporated in its entirety, including any appendices, attachments, exhibits, and references therein.

### TECHNICAL FIELD

This application generally relates to a barrier, and more particularly, to a system for protecting planar structures having a canopy which can be automatically set-up or taken-down dependent on environmental conditions.

### BACKGROUND

The cost of discovering oil, drilling offshore in deep water, transportation across oceans, and more rigorous refining to meet more stringent environmental laws has made oil far less profitable than it once was. In response, billions of dollars have been invested in renewable energy sources over the past decade.

Solar power, the generation of electrical energy from sunlight, has become one of the most popular forms of green technologies. Solar installations in recent years have also begun to expand into residential areas, with governments offering incentive programs to make green energy a more economically viable option. Solar power is a predictably intermittent energy source, meaning that while solar power is not available at all times, it can be predicted with a very good degree of accuracy when it will and will not be available.

These solar panels, however, have become susceptible to damage on a regular occurrence. In some parts of the country, hail storms can do great damage due to the impact of ice particles, which can achieve considerable velocity. When damaged, the solar panels produce less power, which can cost the owner to fix and replace. Use of protective barriers has been attempted in efforts to protect those structures which are susceptible to impact damage. However, many materials which offer significant protection suffer from the drawback that the materials are dense. Protective structures tend to be difficult to deploy when they are retractable, requiring heavy frames and powerful motive elements. Such heavy barriers suffer from the further problem that they obstruct desirable impingements, such as sunlight onto plants and solar collectors.

As a result, a need exists for providing a barrier or other protective system which is effective against hail stones and which allows transmission of sunlight. While the present application is directed to solar panels, those skilled in the relevant art will appreciate that the system provided herein can provide protection to lawns, motor vehicles, solar collectors, photovoltaic and photothermal, windows, and other structures having generally planar surfaces that can be severely damaged if impacted by hail stones or damaged through other environmental conditions.

### SUMMARY

This summary is provided to introduce a selection of concepts in a simplified form that are further described below in the DESCRIPTION OF THE APPLICATION. This summary is not intended to identify key features of the claimed subject matter, nor is it intended to be used as an aid in determining the scope of the claimed subject matter.

In accordance with one aspect of the present application, an assembly for protecting a planar surface is provided. The assembly includes a flexible material and a reel for deploying the flexible material. In addition, the assembly includes a frame disposed to hold the flexible material in a spread out configuration above the planar surface when the flexible material is deployed.

In accordance with another aspect of the present application, a solar panel assembly is provided. The solar panel assembly includes a canopy and a spool for storing the canopy. In addition, the solar panel assembly includes an engine for deploying or retracting the canopy from the spool and at least one processor. The solar panel assembly also includes a memory operatively coupled to the processor, the memory storing program instructions that when executed by the processor, causes the processor to perform processes. These processes include receiving a signal and rotating the engine to deploy the canopy when the signal specifies closing the solar panel assembly. In addition, the solar panel assembly includes rotating the engine to retract the canopy when the signal specifies opening the solar panel assembly.

In accordance with yet another aspect of the present application, a solar panel protection system is provided. The solar panel protection system includes a motor and a covering. In addition, the solar panel protection system includes a frame surrounding at least one photovoltaic module comprising a front edge, a back edge, and first and second longitudinally extending side edges, the first and second longitudinally extending side edges having a track on a top portion thereof. The solar panel protection system also includes a member coupled to the covering for traversing the track on the top portion of the first and second longitudinally extending side edges to deploy and retract the covering using the motor.

### BRIEF DESCRIPTION OF DRAWINGS

The novel features believed to be characteristic of the application are set forth in the appended claims. In the descriptions that follow, like parts are marked throughout the specification and drawings with the same numerals, respectively. The drawing figures are not necessarily drawn to scale and certain figures can be shown in exaggerated or generalized form in the interest of clarity and conciseness. The application itself, however, as well as a preferred mode of use, further objectives and advantages thereof, will be best understood by reference to the following detailed description of illustrative embodiments when read in conjunction with the accompanying drawings, wherein;

FIG. 1 depicts a top perspective view of an exemplary protection system in accordance with one aspect of the present application;

FIG. 2 shows the exemplary protection system closing in accordance with one aspect of the present application;

FIG. 3 illustrates the exemplary protection system closed in accordance with one aspect of the present application;

FIG. 4 is an exemplary pulley for deploying and retracting the canopy in accordance with one aspect of the present application;

FIG. 5 shows an illustrative canopy moving into a locked position in accordance with one aspect of the present application;

FIG. 5A depicts the bar clamps unlocked in accordance with one aspect of the present application;

FIG. 5B represents the illustrative canopy moving in a reversed direction to tighten the canopy in accordance with one aspect of the present application;

FIG. 5C shows the bar clamps locked in accordance with one aspect of the present application;

FIG. 6 is a diagrammatic top plan view of resilient mesh material used in the canopy in accordance with one aspect of the present application;

FIG. 7 is an exemplary protection system having a debris or snow remover in accordance with one aspect of the present application;

FIG. 7A provides a typical cleaner for the exemplary protection system in accordance with one aspect of the present application;

FIG. 7B shows a wiper blade following the cleaner in accordance with one aspect of the present application;

FIG. 7C depicts a buffer pad following the cleaner in accordance with one aspect of the present application;

FIG. 8 provides for an illustrative ice melting element that can be provided with the protection system in accordance with one aspect of the present application;

FIG. 9 represents an exploded perspective view of a protective system arranged to provide close cover in accordance with one aspect of the present application; and

FIG. 10 is another illustration of the protective system in accordance with one aspect of the present application.

### DESCRIPTION OF THE APPLICATION

The description set forth below in connection with the appended drawings is intended as a description of presently-preferred embodiments of the application and is not intended to represent the only forms in which the present application can be constructed and/or utilized. The description sets forth the functions and the sequence of steps for constructing and operating the application in connection with the illustrated embodiments. It is to be understood, however, that the same or equivalent functions and sequences can be accomplished by different embodiments that are also intended to be encompassed within the spirit and scope of this application.

### Overview

Generally described, the present application relates to an effective barrier against hail stones, golf balls, and other small objects which can be propelled against delicate objects and surfaces. In one illustrative embodiment, the barrier can include a resilient, open mesh web material, which can be supported on a frame and stored and deployed from a reel. A motor can be used to deploy or retract the material. When deployed, the material can be provided in a spread out configuration above a planar surface. In one embedment, the barrier can provide a scoop that brushes off debris or other materials from the top of the material. In addition, the barrier can include an apparatus for directly cleaning the planar surface.

While a majority of the embodiments presented herein are directed to solar panels, those skilled in the relevant art will appreciate that the system provided herein can protect lawns, motor vehicles, solar collectors, photovoltaic and photothermal, windows, and other structures having generally planar surfaces that can be severely damaged if impacted by hail stones or damaged through other environmental conditions. Furthermore, the embodiments presented above were for purposes of illustration and should not be construed as limiting the scope of the present application.

### Protection System

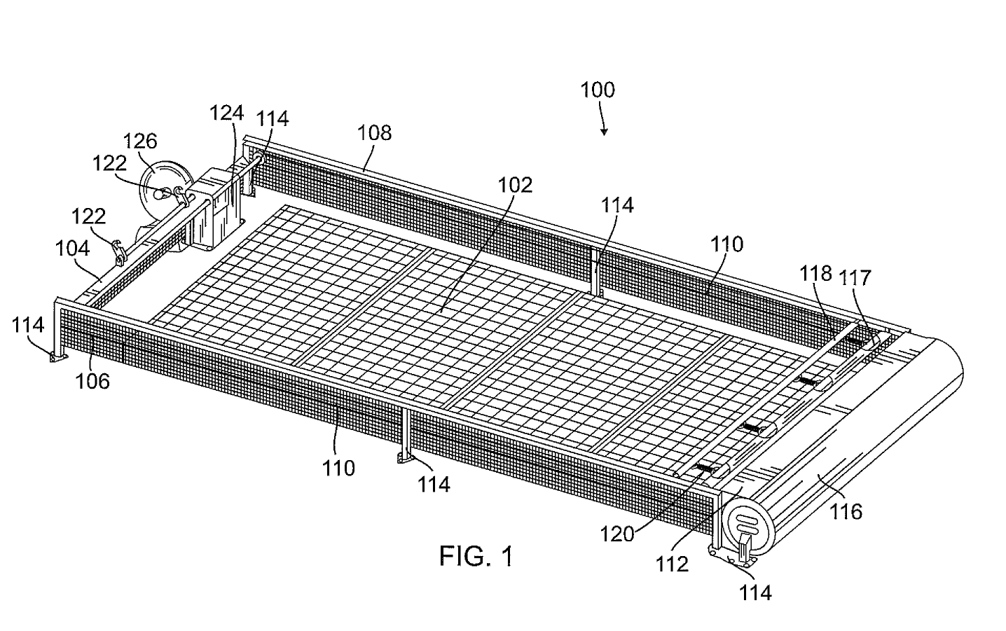

With reference now to FIG. 1, a top perspective view of an exemplary protection system 100 in accordance with one aspect of the present application is provided. While illustrative components of the protection system 100 are provided therein, those skilled in the relevant art will appreciate that there can be fewer or more components within the system 100.

As shown, the protective system 100 can include a frame surrounding a planar structure such as a solar panel 102. The frame can include a front edge 104, back edge (not shown), a first longitudinally extending side edge 106, and a second longitudinally extending side edge 108. The frame can be made of protective screening that allows sun, wind, and other environmental elements to pass through. Generally, however, the frame protects the planar structure 102 from damaging elements. In one embodiment, the frame can be solid on the bottom portion thereby preventing weather elements from coming through and the top portion having the screening material described above. Alternatively, the frame can be made of a material that does not allow the elements to pass through at all. In other embodiments, the side edges 106 and 108 can be made of the screening material while the front edge 104 and back edge can be made of the solid material.

The frame can provide a structure where a protective barrier material or canopy 112 can be held in a spread out configuration above a planar structure being protected. As described above, the planar structure 102 can be a solar panel. In other embodiments, the frame can be placed over lawns, motor vehicles, solar collectors, photovoltaic and photothermal, windows, and other structures having generally planar surfaces. In some embodiments, the planar structure can be built within the frame. For example, the planar structure can be a solar panel such that the frame includes the solar panel for a standalone unit. When the edges are made from a solid material, as described above, the planar structure 102 can be raised by the system 100. For example, when the planar structure 102 is a solar panel, the solar panel can be raised to receive more direct sunlight.

The frame itself can have multiple legs 114 that not only provide support to the frame, but also can be fixed to a structure for proper securing. In one embodiment, the legs 114 can be connected to a rooftop. In another embodiment, the legs 114 can be spikes that can be driven into the ground. While six (6) legs are shown within the frame, those skilled in the relevant art will appreciate that fewer or more legs 114 can be used. Typically, the legs 114 can be a length sufficient to hold other components of the system 100 at a suitable height above the supporting environmental surface, such as the ground (not shown), and suitably spaced above the protected surface such as the solar panel 102.

Continuing with FIG. 1, the first longitudinally extending side edge 106 and the second longitudinally extending side edge 108 can have a track 110 that runs laterally across the entire length of the edges 106 and 108. As will be shown, a canopy 112 can traverse or slide across the track 110.

Associated with the canopy 112 is a canopy spool or reel 116, which can be attached to the back edge of the frame. The reel 116 can store the material by rolling or folding within a storage compartment. The reel 116 can have storage and a spring that can rewind to assist the motor 122, which will be described in more details below. The spring within the reel 116 can cause the canopy 112 to be tightened.

In one embodiment, a motor can be placed within the reel 116. The motor can allow the canopy 112 to be deployed and retracted. A powered actuator can be disposed to rotate the reel 116 selectively in opposed directions corresponding to rolling out the canopy 112 and reeling the canopy 112 onto the reel 116. The powered actuator can include a motor and a controller. The controller can include comprise a radio receiver, so that the reel 116 can be operated responsive to a remote signal. The signal can originate from services such as, but expressly not limited to, the National Oceanic and Atmospheric Administration.

The controller can be understood to include all circuitry and components necessary to carry out the functions as described herein. Remotely operated reversible motor controllers per se are known. Any selected example thereof can be adapted for incorporation into the controller. Power for operating the controller can be provided by a dedicated circuit or by a plug and cord assembly which can be plugged into an ordinary household volt receptacle or ran off solar panels.

A storage facility on the reel 116 can hold the canopy 112 in compact form in the stored condition, which can be for example drawn into a roll. The reel 116 can typically be used to deploy the canopy 112, wherein the canopy 112 is spread over the protected article. The reel can retract the canopy 112 onto the reel 116 from the deployed position by rotating in a reverse direction from that in which the canopy 112 was rolled out.

As further shown in FIG. 1, the canopy 112 can be connected to a second member 118 via a first member 117 and a number of springs 120. While more details of the deploying and retracting of the canopy 112 will be described below, it should be noted that the first and second members 117 and 118 can include a bearing or wheel type structure that allows the members 117 and 118 to freely move or traverse along the track 110. In other embodiments, the members 117 and 118 can be driven by a chain or similar feature.

As recited above, the first member 117 and second member 118 can be connected through a number of springs 120. The springs 120, which will be shown below, can act similarly to a garage door opener. As such, when an actuator switch is contacted, the motor can be reversed tightening the canopy.

On the front end 104, member 118 can be secured by bar clamps 122. The bar clamps 122 can lock member 118 thereby locking member 117. As will be shown, the bar clamps 122 can be used to tighten the canopy 112.

Attached to the front end 104 can be a motor or engine 124 to propel the canopy back and forth in a deployed condition or retracted condition. The motor 124 can use electrical energy to produce mechanical energy. Generally, the motor 124 can run on energy generated by the solar panels 102. As known to those skilled in the art, the solar panels 102 can store energy in a battery or similar device such that the electrical energy can be used for later, and in this case, the motor 124 of the system 100. It can be understood that the current system 100 can be a green technology that uses little to no energy produced by a third party.

While the previous embodiment discussed that the system 100 could use little to no energy from outside sources, in some embodiments, the motor 124 can receive its energy through an electrical outlet. This can be particularly useful for areas where the sun is not seen for months at a time, such as Seattle, Wash.

Previously described, a motor was connected to the reel 116, while shown above a motor 124 can be connected to the front edge 104. A combination of the motors can be used. In another embodiment, the motor connected to the front edge 104 can be used, while in other embodiments, the motor connected to the reel 116 can be used. Those skilled in the relevant art will appreciate that a variety of mechanisms can be used to deploy and retract the canopy 112.

The system 100 can also include a weather detector 126. The weather detector 126 can drive input signals to deploy or retract the canopy 112. For example, when a snow storm is approaching, the weather detector 126 would provide signal to deploy the canopy 112. In other embodiments, the signal can be received from a variety of other sources. The signal, on whether to deploy or retract the canopy 112, can be provided through a centralized location. At the centralized location, an administrator can be used to determine whether the canopy 112 should be opened or closed. In addition, the centralized location can be forwarded how much power is being produced by the system 100. By using software within the system 100, actual statistics can be provided in addition to keeping track of actual energy production.

In another embodiment, the signal can be fed into a computer or some other similar device so that the signals can be provided within the comfort of the user's home. In one embodiment, the signal can be provide through a display such as a television set within the house and can be programmed through the remote control associated with the television set. Those skilled in the relevant art will appreciate that the television set can be provided in numerous types of implementations. For example, the television set can come in the form of an LCD or plasma monitor. Furthermore, those features provided above, allow for plug-and-play capabilities, which can include a flash drive that can be inserted into an USB port of the system 100. The flash drive can then be plugged into a display such as TV screen for showing statistics or monitoring the system 100.

Following along those lines, a plug and play camera can be used to monitor the system 100. The camera can also be used for security purposes. The camera can be embedded on top of the assembly and a signal can be fed to the display. The signal can be propagated through a wireline or wirelessly. In one embodiment, the signal can be fed through the internet so that the assembly 100 can be monitored remotely.

In other embodiments, the system 100 can provide signals to a network. The network can monitor information from a number of systems 100. The information can include energy production from the system 100. Furthermore, the network can detect whether there is a break in the system. This information can be used by solar power companies who use mass grids. In some instances, the power produced by the solar panels 102 can be sold to electrical companies. In this case, the software would be used to detect how much power is being sold.

### Activation

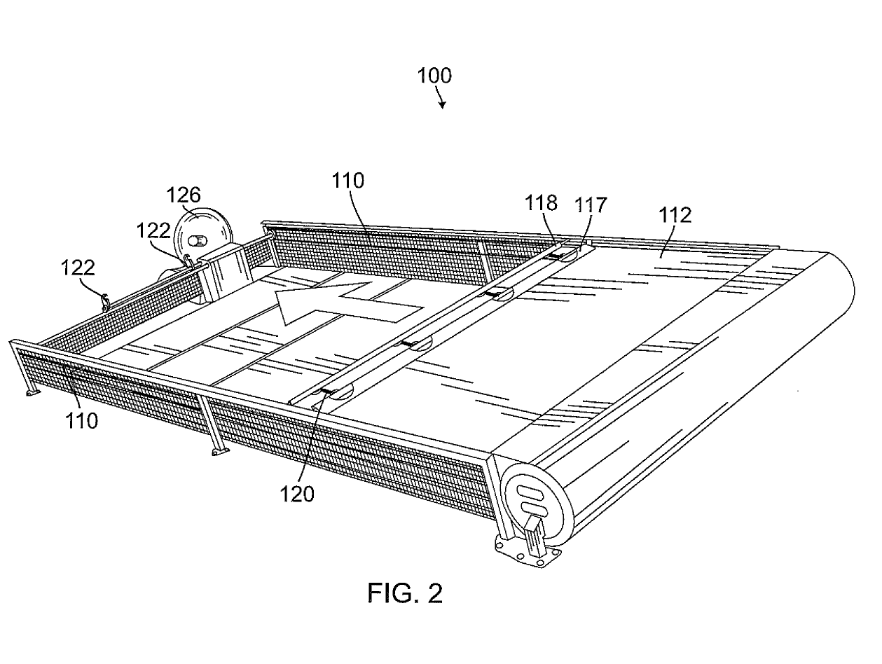

With reference to FIG. 2, the exemplary protection system closing in accordance with one aspect of the present application is provided. In the shown embodiment, the canopy 112 can be closed through a signal received by the weather detector 126. In other embodiments, the canopy 112 can be closed based on the user's decision or some other automated function. The canopy can traverse the track 110 through the first member 117 and the second member 118 via the springs 120.

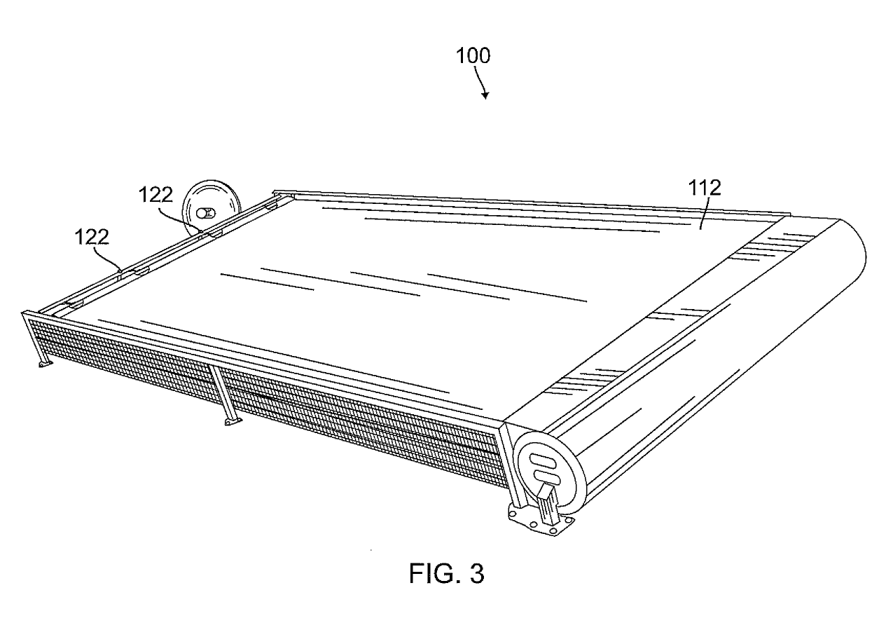

In the embodiment shown, the bar clamps 122 can be in a raised position. The canopy 112 is between a deployed and a retracted condition. The clamps 112 can be in their raised position ready to clamp down on the second member 118. FIG. 3 illustrates the exemplary protection system 100 closed in accordance with one aspect of the present application. As shown, the bar clamps 122 have locked the canopy 112 into a tight position thereby removing any weather elements from damaging the planar structure.

### Track

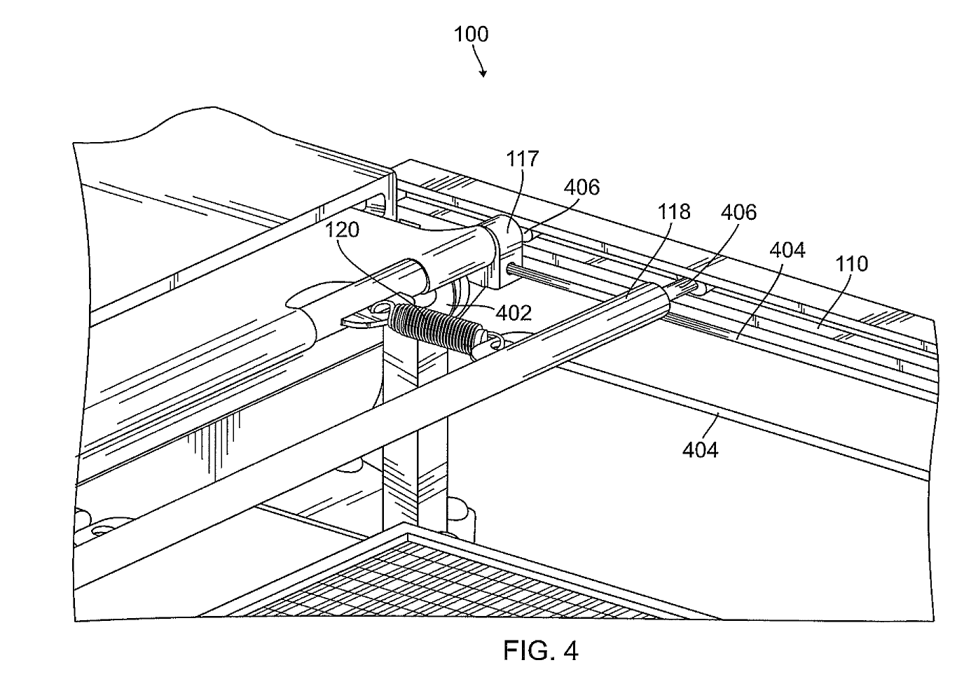

FIG. 4 is an exemplary pulley 402 for deploying and retracting the canopy 112 in accordance with one aspect of the present application. As shown, an exemplary cable loop 404 can be rotated by the pulley 402, which can take the form of a wheel on an axle or shaft. The wheel can have a groove between two flanges around its circumference. The cable loop 404 can be, but is not necessarily limited to, a rope, cable, belt or chain, that usually runs over the wheel and inside the groove.

The cable loop 404 can be fitted within the first member 117 and through the second member 118. When the pulley 402 is rotated, the first member 117 and the second member 118 rotate along a longitudinal axis created by the track 110. Movement within the members 117 and 118 can be generated by wheels 406 formed on the outer edges. In some embodiments, the track 110 and the wheels 406 can be well lubricated so that the members 117 and 118 can freely rotate along the track 110.

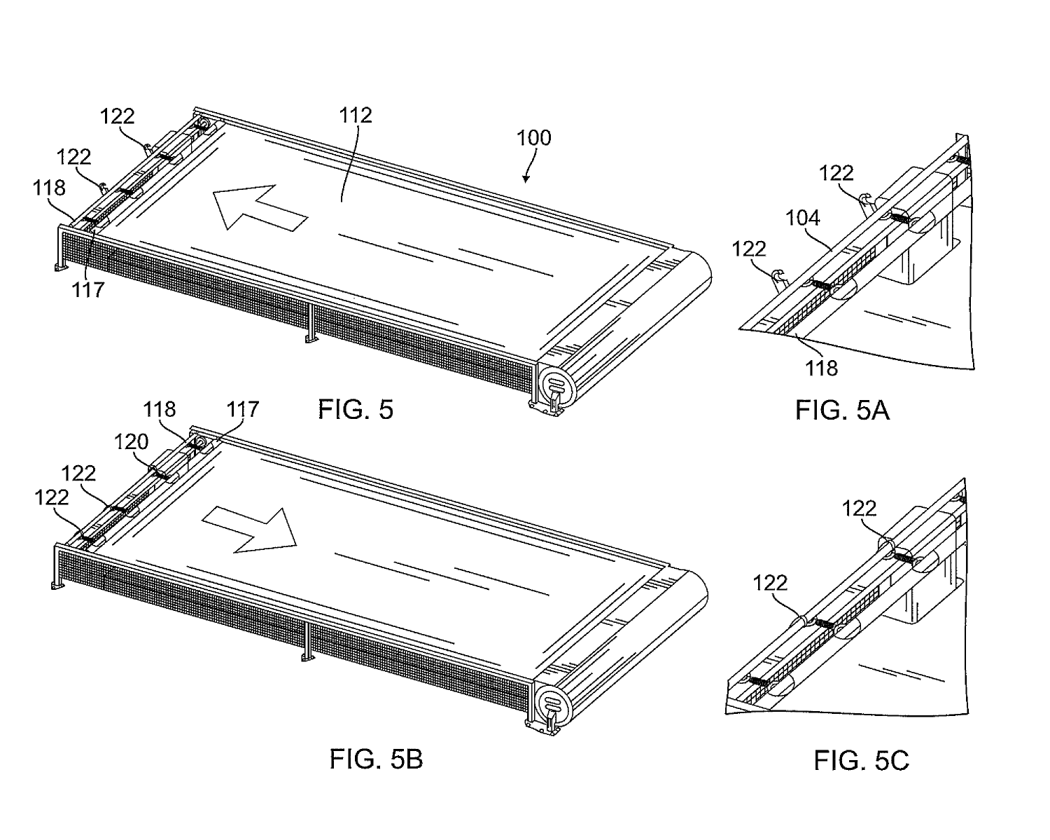

This movement within members 117 and 118 can allow the canopy 112 to be deployed and retracted. FIG. 5 shows an illustrative canopy 112 moving into a locked position in accordance with one aspect of the present application. As initially shown, the canopy 112 begins moving into a position so that member 118 can be locked. FIG. 5A depicts the bar clamps 112 unlocked in accordance with one aspect of the present application. As further shown, the second member 118 is tightly fitted to the front end 104. The bar clamps 122 at this time still remain unlocked.

In FIG. 5B, the illustrative canopy 112 is locked into placed using the bar clamps 112 and moved in a reversed direction to tighten the canopy in accordance with one aspect of the present application. As shown, member 118 is locked and the canopy 112 is reversed using the motor. Through the use of the springs 120, the canopy 112 can be tightened without the fear of the canopy 112 ripping or being damaged so that the canopy 112 can be as strong as possible to deflect incoming objects or weather elements. FIG. 5C shows the bar clamps 122 locked in accordance with one aspect of the present application.

### Canopy

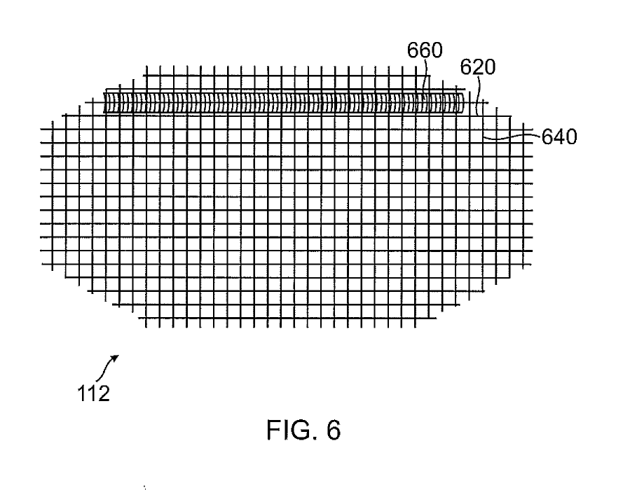

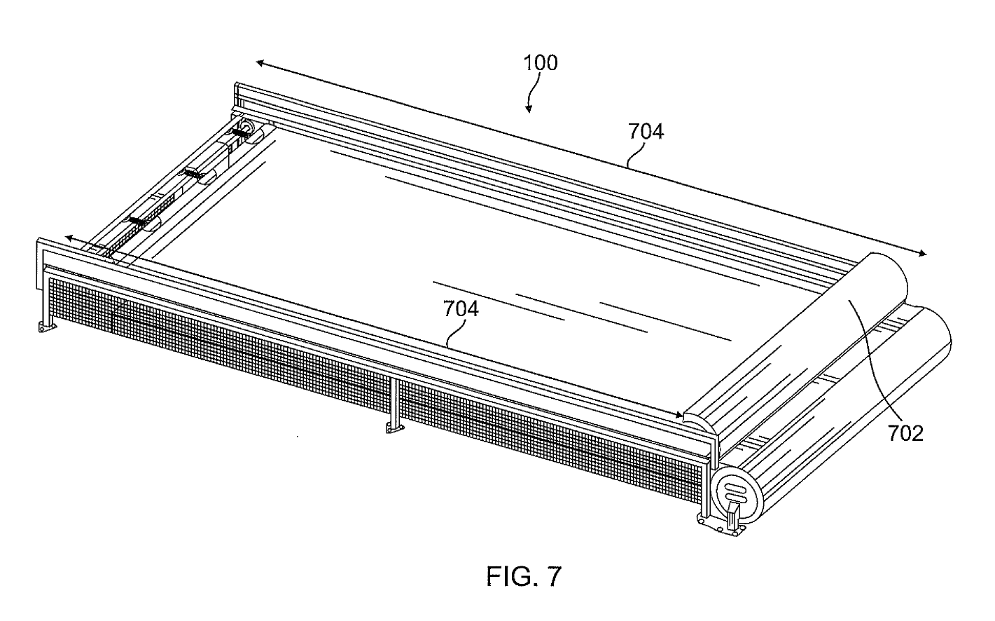

With reference now to FIG. 6, a diagrammatic top plan view of resilient mesh material used in the canopy 112 in accordance with one aspect of the present application is provided. Operatively, the resilient open mesh fabric of suitable mesh size when spaced apart from a protected surface can intercept and decelerate objects so that the objects do not damage the underlying protected surface or object. A resilient open mesh fabric of low density and bulk allows for convenient storage, and can be easily rolled out to a deployed position. Typically, a resilient open mesh web fabric can also pass sunlight and rain, for example, which is advantageous when used to protect lawns, ferns, and other plant life.

With these advantages in mind, the canopy 112 can include a reeled web of resilient open mesh fabric and a supporting frame which holds the reel in operative proximity to and just above the surface being protected. Alternatively, the open mesh fabric can be held at a greater distance above an environmental surface. In one embodiment, the canopy 112 be provided within a number of panels adapted to enclose a three dimensional space.

As recited above, the canopy 112 can be provided with an automatic deployment apparatus which can be remotely actuated. For example, the canopy 112 can include a controller which is responsive to remote communications, and which causes the canopy 112 to be rolled out responsive to a remotely signaled alarm condition such as adverse weather conditions. The canopy 112 can be supported by eyes formed therein, by springs 120 connecting the canopy 112 to a frame, by storage on a reel 116, or in still other ways. In one embodiment, the canopy 112 can incorporate a heating device such as electrical resistive elements for de-icing.

FIG. 6 shows a representative patch of the canopy 112, which is seen to include an open mesh material which is flexible and bi-axially resilient. That is, filaments extending in one orthogonal direction, such as the filament 620, and filaments extending in a perpendicular orthogonal direction, such as the filament 640 are each resilient along their length in the respective orthogonal directions of extension. Also, the individual filaments, such as the filaments 620 and 640 are spaced apart from one another sufficiently to pass light and liquids, while being sufficiently close as to intercept small solid objects such as hail stones, golf balls, coins, pens and pencils, and the like (none shown). A suitable open mesh bi-axially resilient material is that typically used as the constituent material in trampolines (not shown). The material can be modified to be suitable for prolonged outdoor use, such as for example incorporating a chemical barrier to ultraviolet rays.

The canopy 112 can include any suitable mesh size. That is, a mesh size able to protect against hail. Suitable mesh size ranges include mesh sizes of point five (0.5) cm by point five (0.5) cm to one point five (1.5) cm by one point five (1.5) cm. For example, one (1) cm by one (1) cm mesh size. The canopy 112 can be, for example, one (1) cm by one (1) cm rubberized mesh material.

The canopy 112 can have incorporated therein a flexible heating element 660 for melting ice which can accumulate on the canopy 112 for example hail. The flexible heating element 660 can include any known electric resistive heating cable, such as either constant wattage or self-limiting heating cables. Such heating cables are commercially available from Raychem Corporation of Menlo Park, Calif., Nelson Heat Trace of East Granby, Conn., and other manufacturers. The flexible heating element 660 can be connected to electrical power serving the controller.

### Scoop

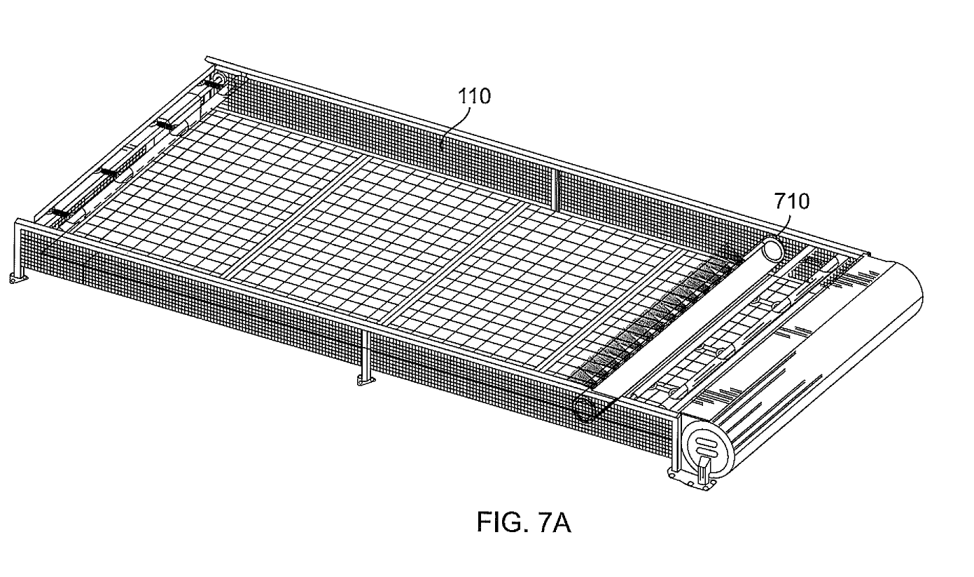

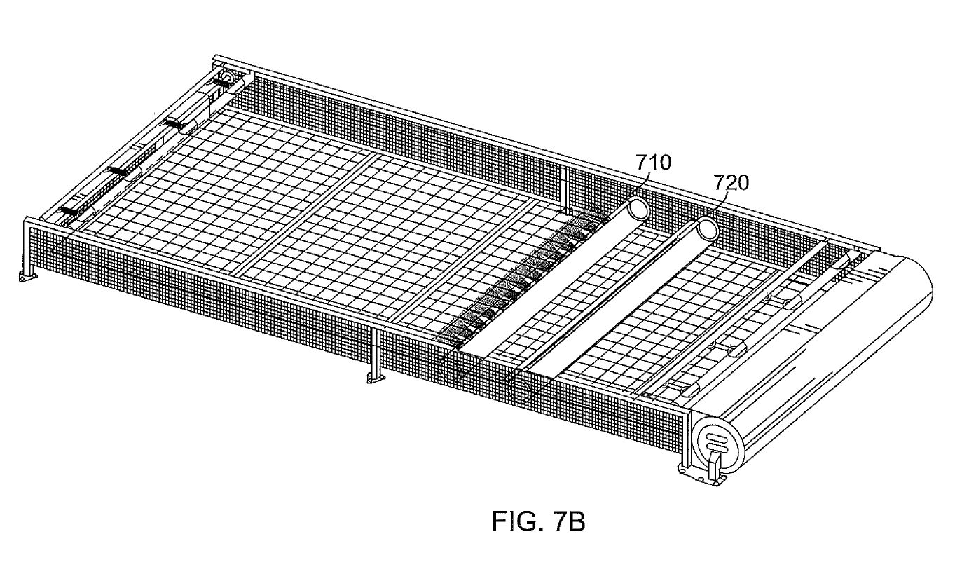

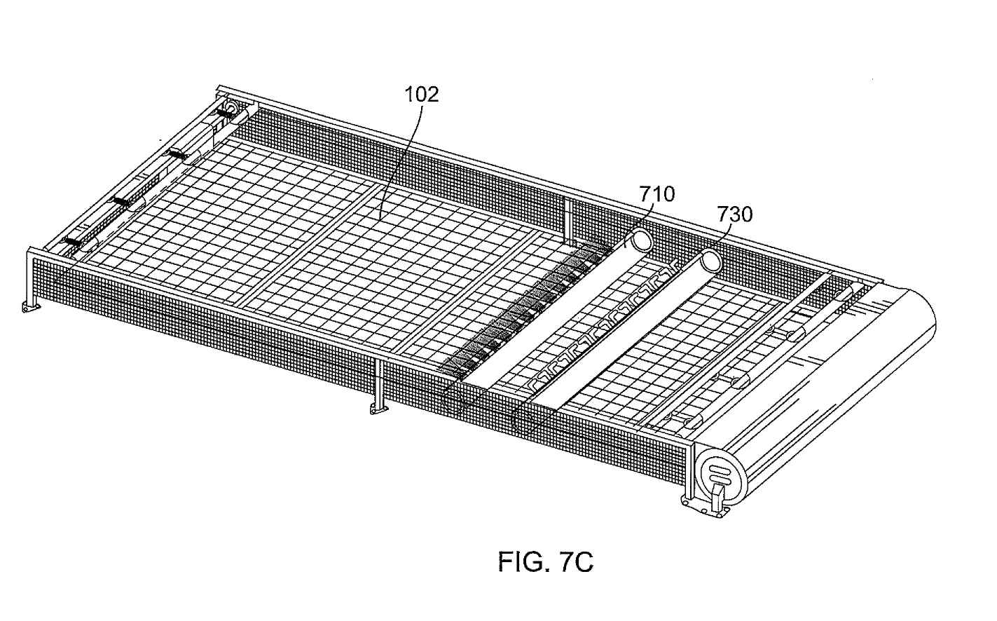

In some parts of the country, the amount of snow or other debris that builds upon the system 100 can be significant. The amount of snow that can be melted through the heating element 660 described above can generally be very minimal. As a result, FIG. 7 is an exemplary protection system 100 having a debris or snow remover 702 in accordance with one aspect of the present application.

As shown, the remover 702 can be placed on top of the canopy 112. When a large amount of materials are placed on top of the canopy 112, the remover 702 can simply traverse along a parallel longitudinal axis to the track 110, which can be denoted herein as another track 704. Typically, the remover 702 operates when the canopy 112 is still in a deployed condition. Those skilled in the relevant art will appreciate that the remover 702 can use several back and forth motions to completely remove the debris that is on the canopy 112.

The remover 702 can take the form of a C-Scoop known to those skilled in the relevant art. Other optimal shapes for removing the debris off the canopy 112 can be used as well. In one embodiment, the remover 702 can deflect material to the sides of the system 100. More relevant to the FIGURES shown above, where the system 100 is attached to a roof, the remover 702 can push the debris or elements to one side such as the side facing towards the ground. The debris can include, but is not limited to, leaves, snow, hail, branches, etc.

In one embodiment, a blower can be attached to the top portion of the canopy 112. The blower would not traverse any path, but instead by turned on to blow snow or leaves away from the top portion of the canopy 112.

### Cleaner

As described above, the canopy 112 can include a mesh-type material that can allow some elements to come within the frame of the system 100. As such, the planar structure 102 can often times get dirty and should be cleaned. FIG. 7A provides a typical cleaner 710 for the exemplary protection system in accordance with one aspect of the present application. The cleaner 710 can traverse a path similar to that of the canopy 112, but below the track 110.

As shown, the cleaner 710 can be placed right above the planar structure 102. The cleaner 710 can include a sprayer that releases liquid that removes particles from the planar structure 102. The liquid can include a combination of warm water and dishwashing soap. The warm water can be heated by the solar panel 102 itself.

The cleaner 710, in some occasions, cannot clean all the debris or materials left on the planar structure 102. FIG. 7B shows a wiper blade 720 following the cleaner 710 in accordance with one aspect of the present application. Typically, the wiper blade 720 can be retractable and/or flexible and point in a downwards direction. After the liquid has been dispensed over the planar structure 102, a wiper blade 720 can follower thereafter. The wiper blade 720 can wipe the liquid thereby cleaning any materials or residue left over from the cleaner 710. The wiper blade 720 can be angled such that the materials in front of the wiper blade 720 do not collect in front of it. The wiper blade 720 can use the same track as the one used by the cleaner 710.

In another embodiment, as depicted in FIG. 7C, a buffer pad 730 following the cleaner 710 in accordance with one aspect of the present application can be used. Typically, the buffer pad 730 can be retractable and/or flexible and point in a downwards direction. The buffer pad 730 can use the same track as the one used by the cleaner 710. Those skilled in the relevant art will appreciate that a combination of those elements provided above can be used and those embodiments described above, do not limit the systems and methods for cleaning the planar structure 102.

### Heating Element

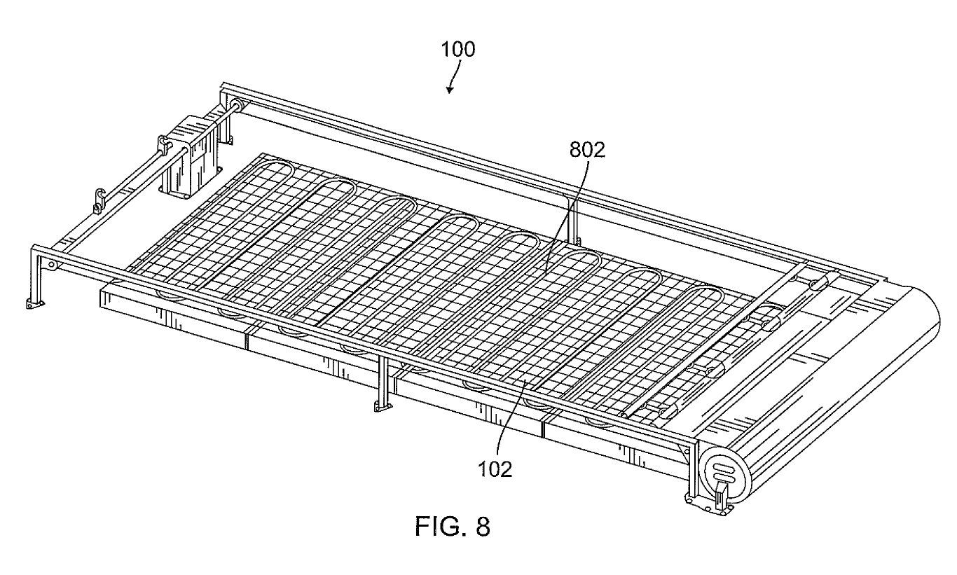

FIG. 8 provides an illustrative ice melting element 802 that can be provided with the protection system 100 in accordance with one aspect of the present application. The melting element 802 can be fabricated to be underneath the glass of the solar panel 102. Alternatively, the melting element 802 can be installed above the solar panel 102.

### Other Embodiments

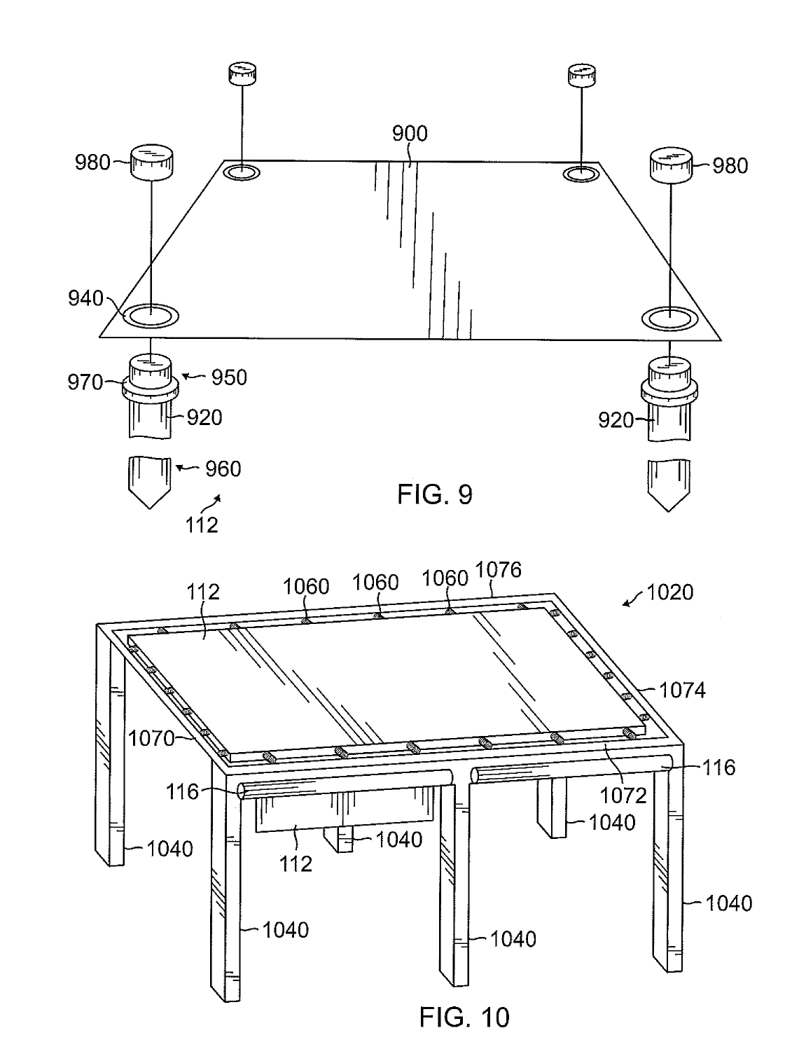

The canopy 112, described above, can also be used within numerous other embodiments. FIG. 9 represents an exploded perspective view of a protective system arranged to provide close cover in accordance with one aspect of the present application. As employed herein, the term “ground cover” is not intended to signify that the canopy 112 is necessarily in close proximity to the ground. Rather, the term “ground cover” is intended in a more general sense signifying that any surface is covered in close proximity by the canopy 112.

The canopy 112 can include an open mesh protective barrier material 900 which is flexible and bi-axially resilient, and a plurality of legs 920 disposed to engage the ground or any generally horizontal supporting environmental surface (not shown). The open mesh protective barrier material 900 can be similar to that described above. Each one of the legs 920 can have a proximal end 950 fixed to said barrier material 900 such as by penetrating the latter by for example passing through reinforcing eyes 940 which have been incorporated into the open mesh protective barrier material 900 as shown, and distal ends 960 having ground penetrating structure. As employed herein, ground penetrating structure can include points, or can be otherwise configured. For example, a leg 920 of diameter of two inches can be provided with an unpainted downwardly projecting spike (not shown) of one quarter inch diameter. Such a spike could readily penetrate moist earth with only manual pressure, and would therefore be regarded as ground penetrating structure. Another example of ground penetrating structure may be anchors (not shown) which are separate from the leg 920 and which can be driven into the ground and which can receive and engage the leg 920 by interfit, fasteners, or other means.

The proximal end 950 can be engaged by a removable cap 980 which is dimensioned and configured to engage the proximal end 950 by friction, threading, or in any other suitable way. A flange 970 can be provided as a stop to limit downward movement of the open mesh protective barrier material 900 or the eye 940. Thus, the open mesh protective barrier material 900 can be removably engaged with each leg 920.

The protective barrier assembly 980 can hold the open mesh protective barrier material 900 in a spread out orientation as depicted with the legs 920 unconnected to one another by rigid material, such as by a rigid frame member (not shown). The spread out orientation can rely upon stable engagement of the ground or other environmental substrate by the legs 920.

FIG. 10 is another embodiment for using the canopy 112 in accordance with one aspect of the present application. As shown, the barrier 1020, which uses a number of canopies 112, can be arranged to enclose a three dimensional space. This space can be used to store objects, or can be used for other purposes. The barrier 1020 can include a frame which is disposed to hold at least one barrier panel in a spread out configuration, and as will be further explained hereinafter, to hold at least one canopy 112 in a stowed condition.

A canopy 112 comprising an open mesh protective barrier material, which can be similar in consistency of the canopy 112 described above, for example, can be held in a generally horizontal orientation. It should be mentioned at this point that orientation terms such as vertical and horizontal, up and down, and the like refer to the drawings. Such terms are to be regarded as illustrational only for semantic purposes of explaining the invention, and not in a limiting sense. Obviously orientations may be changed to suit any particular application or variation of the inventive elements.

The canopy 112 can be held on rigid frame members 1070, 1072, 1074, and 1076 of the frame so as to surround the canopy 112. The frame can include a plurality of rigid legs 1040 which depend downwardly from the rigid frame members 1070, 1072, 1074, and 1076 when the frame is in the deployed condition depicted in FIG. 10. The legs 1040 can each engage a horizontal environmental supporting stratum such as the ground or a floor surface (neither shown), either by resting on the selected surface or by penetration, with or without fastening means,

The canopy 112 can be secured to the rigid frame members 1070, 1072, 1074, and 1076 coils springs 1060 the way that the resilient elastic web of a trampoline (not shown) is secured to the frame of the trampoline. Additional canopies 112 can be held in reels 700 which are mounted to the frame. In FIG. 10, one canopy 112 is visible, shown depending from its associated reel 116 in a partially deployed condition and at a non-parallel angle to a horizontal orientation when the legs 1040 engage the horizontal environmental supporting stratum. In the fully deployed condition, the exposed canopy 112 can after being rolled out extend to the bottom of the legs 1040 for example. The other reel 112 can fully enclose its associated canopy 112, the associated canopy 112 thus being stored in a stowed condition and therefore not being visible in FIG. 10.

The orientations of the various canopies 112 can be varied from the horizontal and vertical orientations depicted in FIG. 10. Orientation of the various elements can be non-perpendicular. Any of the various barrier panels can be mounted on springs, such if the springs 1060 supporting the canopy 112, any can be reeled, and any can be mounted in another. Any of the various canopies 112, can be motorized or remotely controlled as described with reference to FIG. 1.

A reel 116 can be modified in diverse ways. For example, a reel 116 can be powered or in some cases, manually operated. A reel 116 can incorporate an operating handle, a return spring, or other features. A reel 116 can be enclosed as depicted, or alternatively can hold its associated canopy 112.

### Systems, Methods, and Operations

In accordance with one aspect of the present application, an assembly for protecting a planar surface is provided. The assembly includes a flexible material and a reel for deploying the flexible material. In addition, the assembly includes a frame disposed to hold the flexible material in a spread out configuration above the planar surface when the flexible material is deployed.

In one embodiment, the reel is capable of deploying the flexible material when the flexible material is stored within the reel and capable of retracting the flexible material into the reel after the flexible material is deployed. In one embodiment, the assembly includes an actuator disposed to rotate the reel selectively in opposed directions corresponding to deploying the flexible material from the reel and retracting the flexible material into the reel to tighten the flexible material. In one embodiment, a wireless controller for activating the actuator responsive to a remote signal. In one embodiment, the flexible material comprises a protective mesh material that is bi-axially resilient. In one embodiment, the assembly includes a heating element disposed in the flexible material to melt ice in the vicinity of the flexible material.

In accordance with another aspect of the present application, a solar panel assembly is provided. The solar panel assembly includes a canopy and a spool for storing the canopy. In addition, the solar panel assembly includes an engine for deploying or retracting the canopy from the spool and at least one processor. The solar panel assembly also includes a memory operatively coupled to the processor, the memory storing program instructions that when executed by the processor, causes the processor to perform processes. These processes include receiving a signal and rotating the engine to deploy the canopy when the signal specifies closing the solar panel assembly. In addition, the solar panel assembly includes rotating the engine to retract the canopy when the signal specifies opening the solar panel assembly.

In one embodiment, the signal is dependent on environmental conditions. In one embodiment, the memory storing program instructions, when executed by the processor, causes the processor to determine energy production of the solar panel assembly. In one embodiment, the memory storing program instructions, when executed by the processor, causes the processor to provide the usage of energy of the solar panel assembly to a central facility. In one embodiment, the central facility determines whether there is a break in the solar panel assembly. In one embodiment, the solar panel assembly includes a display for tracking the solar panel assembly.

In one embodiment, the solar panel assembly includes a plug and play device for monitoring the solar panel assembly. In one embodiment, rotating the engine to deploy the canopy includes positioning the canopy in line with a bar clamp, locking the bar clamp to the canopy, and reversing the canopy while side bar clamp is locked to the canopy to tighten the canopy. In one embodiment, rotating the engine to retract the canopy includes unlocking the bar clamp from the canopy and reversing the canopy.

In accordance with yet another aspect of the present application, a solar panel protection system is provided. The solar panel protection system includes a motor and a covering. In addition, the solar panel protection system includes a frame surrounding at least one photovoltaic module comprising a front edge, a back edge, and first and second longitudinally extending side edges, the first and second longitudinally extending side edges having a track on a top portion thereof. The solar panel protection system also includes a member coupled to the covering for traversing the track on the top portion of the first and second longitudinally extending side edges to deploy and retract the covering using the motor.

In one embodiment, the solar panel protection system includes a bar clamp coupled to the front edge of the frame. In one embodiment, the member includes a first structure capable of being coupled to a bar clamp when the covering is deployed, a second structure coupled to the covering, and at least tightening element connecting the first structure and the second structure for tightening the covering when deployed.

In one embodiment, the solar panel protection system includes a scoop positioned above the track to remove debris or other material from the covering. In one embodiment, the solar panel protection system includes a secondary track on the first and second longitudinally extending side edges, wherein the secondary track is placed above the photovoltaic module, the second track used by an element for cleaning the photovoltaic module. In one embodiment, the cleaning element includes a liquid dispensing member and a wiper blade or the liquid dispensing member and a buffer device. In one embodiment, the solar panel protection system includes manual override switch. In one embodiment, the at least one photovoltaic module provides power to the motor.

The foregoing description is provided to enable any person skilled in the relevant art to practice the various embodiments described herein. Various modifications to these embodiments will be readily apparent to those skilled in the relevant art, and generic principles defined herein can be applied to other embodiments. Thus, the claims are not intended to be limited to the embodiments shown and described herein, but are to be accorded the full scope consistent with the language of the claims, wherein reference to an element in the singular is not intended to mean “one and only one” unless specifically stated, but rather “one or more.” All structural and functional equivalents to the elements of the various embodiments described throughout this disclosure that are known or later come to be known to those of ordinary skill in the relevant art are expressly incorporated herein by reference and intended to be encompassed by the claims. Moreover, nothing disclosed herein is intended to be dedicated to the public regardless of whether such disclosure is explicitly recited in the claims.

What is claimed is:

1. An assembly for protecting a planar surface comprising:
a flexible material;
a reel for deploying said flexible material; and
a frame disposed to hold said flexible material in a spread out configuration above said planar surface when said flexible material is deployed.

2. The assembly of claim 1, wherein said reel is capable of deploying said flexible material when said flexible material is stored within said reel and capable of retracting said flexible material into said reel after said flexible material is deployed.

3. The assembly of claim 2, further comprising an actuator disposed to rotate said reel selectively in opposed directions corresponding to deploying said flexible material from said reel and retracting said flexible material into said reel to tighten said flexible material.

4. The assembly of claim 3, further comprising a wireless controller for activating said actuator responsive to a remote signal.

5. The assembly of claim 1, wherein said flexible material comprises a protective mesh material that is bi-axially resilient.

6. The assembly of claim 1, further comprising a heating element disposed in said flexible material to melt ice in the vicinity of said flexible material.

7. A solar panel assembly comprising:
a canopy;
a spool for storing said canopy;
an engine for deploying or retracting said canopy from said spool;
at least one processor; and
a memory operatively coupled to said processor, said memory storing program instructions that when executed by said processor, causes said processor to:
receive a signal;
rotate said engine to deploy said canopy when said signal specifies closing said solar panel assembly;
rotate said engine to retract said canopy when said signal specifies opening said solar panel assembly.

8. The solar panel assembly of claim 7, wherein said signal is dependent on environmental conditions.

9. The solar panel assembly of claim 7, wherein said memory storing program instructions, when executed by said processor, causes said processor to determine energy production of said solar panel assembly.

10. The solar panel assembly of claim 7, wherein said memory storing program instructions, when executed by said processor, causes said processor to provide said usage of energy of said solar panel assembly to a central facility.

11. The solar panel assembly of claim 10, wherein said central facility determines whether there is a break in said solar panel assembly.

12. The solar panel assembly of claim 7, further comprising a display for tracking said solar panel assembly.

13. The solar panel assembly of claim 7, further comprising a plug and play device for monitoring said solar panel assembly.

14. The solar panel assembly of claim 7, further comprising a camera.

15. The solar panel assembly of claim 7, wherein rotating said engine to deploy said canopy comprises:
positioning said canopy in line with a bar clamp;
locking said bar clamp to said canopy; and
reversing said canopy while side bar clamp is locked to said canopy to tighten said canopy.

16. The solar panel assembly of claim 15, wherein rotating said engine to retract said canopy comprises:
unlocking said bar clamp from said canopy; and
reversing said canopy.

17. A solar panel protection system comprising:
a motor;
a covering;
a frame surrounding at least one photovoltaic module comprising a front edge, a back edge, and first and second longitudinally extending side edges, said first and second longitudinally extending side edges having a track on a top portion thereof; and
a member coupled to said covering for traversing said track on said top portion of said first and second longitudinally extending side edges to deploy and retract said covering using said motor.

18. The solar panel protection system of claim 17, further comprising a bar clamp coupled to said front edge of said frame.

19. The solar panel protection system of claim 18, wherein said member comprises:
a first structure capable of being coupled to a bar clamp when said covering is deployed;
a second structure coupled to said covering; and
at least tightening element connecting said first structure and said second structure for tightening said covering when deployed.

20. The solar panel protection system of claim 17, further comprising a scoop positioned above said track to remove debris or other material from said covering.

21. The solar panel protection system of claim 17, further comprising a secondary track on said first and second longitudinally extending side edges, wherein said secondary track is placed above said photovoltaic module, said second track used by an element for cleaning said photovoltaic module.

22. The solar panel protection system of claim 21, wherein said cleaning element comprises a liquid dispensing member and a wiper blade or said liquid dispensing member and a buffer device.

23. The solar panel protection system of claim 17, further comprising a manual override switch.

24. The solar panel protection system of claim 17, wherein said at least one photovoltaic module provides power to said motor.
